(19) United States
(12) Patent Application Publication
(10) Pub. No.: US 2002/0028552 A1
(43) Pub. Date: Mar. 7, 2002

(54) CAPACITOR OF SEMICONDUCTOR INTEGRATED CIRCUIT AND ITS FABRICATING METHOD

(76) Inventors: KI-YOUNG LEE, SUWON-CITY (KR); SEOK-WOO HONG, SUWON-CITY (KR)

Correspondence Address: THE LAW OFFICES OF EUGENE M. LEE, PLLC, 1101 WILSON BOULEVARD, SUITE 2000, ARLINGTON, VA, 22209, US

(21) Appl. No.: 09/389,491

(22) Filed: Sep. 3, 1999

(30) Foreign Application Priority Data
Oct. 17, 1998 (KR) 98-43463

(51) Int. Cl. H01L 21/8242

(52) U.S. Cl. 438/243; 438/244; 438/386

(57) ABSTRACT

A semiconductor integrated circuit capacitor is provided which includes an insulating substrate and a lower electrode disposed on a predetermined part of the insulating substrate. The capacitor also includes an interlevel insulating layer disposed on the insulating substrate and on the lower electrode, and a via hole having sidewalls, whereby the via hole passes through the interlevel insulating layer and exposes a predetermined surface of the lower electrode. The capacitor also includes a spacer disposed on the sidewalls of the via hole, and a dielectric layer disposed on: (i) a bottom surface of the via hole adjacent to the predetermined surface of the lower electrode; (ii) a predetermined part of the insulating layer; and (iii) the spacer. The capacitor also includes an upper electrode disposed on a predetermined part of the interlevel insulating layer and disposed on the dielectric layer. A method of making the semiconductor integrated circuit capacitor also is disclosed.

### BACKGROUND OF THE INVENTION

1. Field of the Invention

The present invention relates to a semiconductor integrated circuit capacitor and to a method of fabricating the semiconductor integrated circuit capacitor. More particularly, the present invention relates to a capacitor having a metal insulator metal (hereinafter, referred to as “MIM”) structure, which can be used in a logic circuit or an analog circuit. The present invention also relates to methods of making such MIM capacitors.

2. Description of the Related Art

A semiconductor integrated circuit can generally be classified into two classes: (i) a digital integrated circuit, also referred to as a logic circuit whose output signal is ON/OFF depending on the variation of an input signal; and (ii) an analog integrated circuit, also referred to as an analog circuit whose output signal is varied linearly depending on the variation of an input signal. These two classes of integrated circuits can memorize information depending on the presence of electrons charged in a capacitor regardless of whether the circuit is a digital circuit or an analog circuit. Accordingly, while fabricating the capacitor, its capacitance should be isolated from influences brought about by variations in voltage or temperature in order to maintain normal operating characteristics of these circuits.

Thus, current trends in fabricating a semiconductor integrated circuit (CMOS analog circuit) prepare the capacitor having a Polysilicon-Insulator-Polysilicon (PIP) structure or a MIM structure that is independent from these variations, in contrast to the conventional metal-oxide semiconductor field-effect transistor (MOSFET) capacitor or junction capacitor. The MIM-structured capacitor is disadvantageous because it has a larger capacitance per a unit area than the PIP capacitor. The MIM structure has, however, when compared to the PIP structure, a good Voltage Coefficient of Capacitance (VCC), which denotes a decreased variation in capacitance according to variations in voltage. The MIM-structured capacitor also has a good Temperature Coefficient of Capacitance (TCC), which denotes a decreased variation in capacitance according to variations in temperature. For example, a conventional MIM capacitor usually has a VCC of 60 parts per million (ppm)/V and a TCC of 70 ppm/° C., whereas a conventional PIP capacitor usually has a VCC of 220 ppm/V and a TCC of 120 ppm/° C. Therefore, the MIM capacitor is more useful in fabricating a precise analog product, and today, both the logic circuits and analog circuits typically are fabricated to have a MIM-structured capacitor.

FIGS. 1 to 4 illustrate a processing method for fabricating a capacitor having a MIM structure useful in a conventional logic circuit or analog circuit. With reference to the drawings, the fabricating method will be described below.

As illustrated in FIG. 1, a first conductive layer (typically comprised of an aluminum-containing (Al) alloy) is formed on an insulating substrate 100 by a random metallization process, and then etched using a photoresist pattern (not shown) as a mask to define a capacitor formation part and a wire formation part. This random metallization and etching process simultaneously forms a first wire line 102b and a lower electrode 102a on the substrate 100. In this case, the first wire line 102b is formed to be connected electrically with a random wire line in the insulating substrate 100 by means of a conductive plug (not shown).

As illustrated in FIG. 2, a planarized interlevel insulating layer 104 is formed on insulating layer 100, which now includes the first wire line 102b and the lower electrode 102a. The planarized interlevel insulating layer 104 then is selectively etched to thereby expose a predetermined part of the surface of the lower electrode 102a, thus forming a first via hole h1 in the insulating layer 104.

As illustrated in FIG. 3, a dielectric layer 106 is formed on the surface inside the first via hole h1, and on the interlevel insulating layer 104 by using a CVD method. The dielectric layer 106 and the interlevel insulating layer 104 then are selectively etched to expose a predetermined surface of the first wire line 102b, thereby forming a second via hole h2 in the insulating layer 104 and dielectric layer 106. The second via hole h2 typically is narrower in width when compared to the first via hole h1, as shown in FIG. 3. The dielectric layer 106 usually is formed using a multi-level structure of plasma Si-oxide/plasma Si-nitride or of plasma Si-oxide/plasma-oxynitride. Thereafter, a sputter etching, also referred to as RF sputter etching, using RF (Radio Frequency) bias is performed to remove an oxide layer that may remain on the exposed surface of the first wire line 102b. Oxide layers that may remain on the surface of wire line 102b include, for example, an etching by-product (e.g., Al₂O₃, or polymer) generated in the step of etching the interlevel insulating layer 104 and dielectric layer 106, or a natural oxide layer.

As illustrated in FIG. 4, a conductive plug 108 (typically comprised of a tungsten (W) material) is selectively formed only in the second via hole h2. A second conductive layer of an Al alloy then is formed on the overall area of the resulting surface, and etched by using a photoresist pattern (not shown) as a mask to define a capacitor formation part (102a/106/110a) and a wire line formation part (102b/108/110b). This etching process simultaneously forms a second wire line 110b and an upper electrode 110a, thereby completing the process.

As a consequence, a wire line is formed on a predetermined part of the insulating layer 100 in the successively deposited multi-level structure of first and second wire lines 102b and 110b, putting the conductive plug 108 therebetween. In addition, a capacitor having a MIM structure is formed on the insulating layer 100 on one side of the wire line. As shown in FIG. 4, the capacitor having the MIM structure is comprised of the lower electrode 102a and the upper electrode 110a of an Al alloy material with the dielectric layer 106 therebetween.

It has been found that if a capacitor for use in a logic or analog circuit is fabricated using the above-described process, the following problems are generated during the process progression. When etching the interlevel insulating layer 104 for forming the first via hole h1, a part of the lower electrode 102a also is anisotropically etched with the interlevel insulating layer 104. Thus, when the process is completed, a part of the lower electrode 102a on the external lower side of the first via hole h1 is undercut and a groove is generated therein.

When the dielectric layer 106 is deposited, the dielectric layer may fill in the groove imperfectly, thus causing a disconnection inferiority of the dielectric layer. With this disconnection inferiority, the circuit cannot have a uniform capacitance because of power leakage, and thus the characteristic properties of the capacitor is decreased. In the extreme case, the capacitor may be broken, resulting in a decrease of yield. A considerable amount of research and development therefore has been expended into looking for a solution to these problems.

FIG. 5 is an enlarged diagram of part “I” of FIG. 3. As shown in FIG. 5, the parts denoted by reference “A” show where the disconnection inferiority of dielectric layer can be generated in the groove formed by undercutting of the lower electrode 102a.

### SUMMARY OF THE INVENTION

There exists a need to develop a semiconductor integrated circuit capacitor that does not suffer from the aforementioned infirmaries. Accordingly, the present invention is directed to a semiconductor integrated circuit capacitor and its fabricating method that substantially obviates one or more of the problems due to the limitations and the disadvantages of the related art. A feature of the present invention therefore is to provide a semiconductor integrated circuit capacitor, and a method of effectively making the capacitor. The inventive capacitor preferably is used in a logic circuit and/or an analog circuit.

In accordance with these and other features of the present invention, as embodied and broadly described, there is provided a semiconductor integrated circuit capacitor that includes:

an insulating substrate;

a lower electrode disposed on a predetermined part of the insulating substrate;

an interlevel insulating layer disposed on the insulating substrate and on the lower electrode;

a via hole having sidewalls, whereby the via hole passes through the interlevel insulating layer and exposes a predetermined surface of the lower electrode;

a spacer disposed on the sidewalls of the via hole;

a dielectric layer disposed on: (i) a bottom surface of the via hole adjacent to the predetermined surface of the lower electrode; (ii) a predetermined part of the insulating layer; and (iii) the spacer; and

an upper electrode disposed on a predetermined part of the interlevel insulating layer and disposed on the dielectric layer.

In accordance with an additional feature of the invention, there is provided a method of making a semiconductor integrated circuit capacitor by:

providing an insulating substrate;

simultaneously forming a first wire line and a lower electrode on predetermined surfaces of the insulating substrate;

forming an interlevel insulating layer on the substrate and on the first wire line and lower electrode;

selectively etching the interlevel insulating layer to expose a predetermined surface of the lower electrode and a predetermined surface of the first wire line thereby simultaneously forming in the interlevel insulating layer: (i) a first via hole having sidewalls and disposed above the lower electrode; and (ii) a second via hole disposed above the first wire line;

forming a conductive layer on the interlevel insulating layer and in the first and second via holes;

etching back the conductive layer to form: (i) a spacer on the sidewalls of the first via hole; (ii) a conductive plug in the second via hole; and (iii) an exposed surface containing the spacer, conductive plug, the predetermined surface of the lower electrode, and predetermined surfaces of the interlevel insulating layer;

forming a dielectric layer on the exposed surface;

removing the dielectric layer on the exposed surface except for a predetermined portion of the dielectric layer disposed on the spacer and predetermined surface of the lower electrode; and

simultaneously forming: (i) a second wire line connected to the conductive plug; and (ii) an upper electrode connected to the dielectric layer.

It is to be understood that both the foregoing general description and the following detailed description are exemplary and explanatory and are intended to provide a further explanation of the invention as claimed. Additional features and advantages of the invention will be set forth in the description which follows and, in part, will be apparent from the description, or may be learned by practice of the invention. The objectives and other advantages of the invention will be realized and attained by the structure particularly pointed out in the written description and claims hereof as well as the appended drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description, serve to explain the principles of the invention.

In the drawings:

FIGS. 1 to 4 illustrate a method of manufacturing a conventional logic and/or analog circuit capacitor having a MIM structure;

FIG. 5 is an expanded diagram of part I of FIG. 3, illustrating a process inferiority caused in fabricating a capacitor based upon the process illustrated in FIGS. 1 to 4; and

FIGS. 6 to 10 illustrate a method of making a logic and/or analog circuit capacitor having a MIM structure in accordance with the present invention.

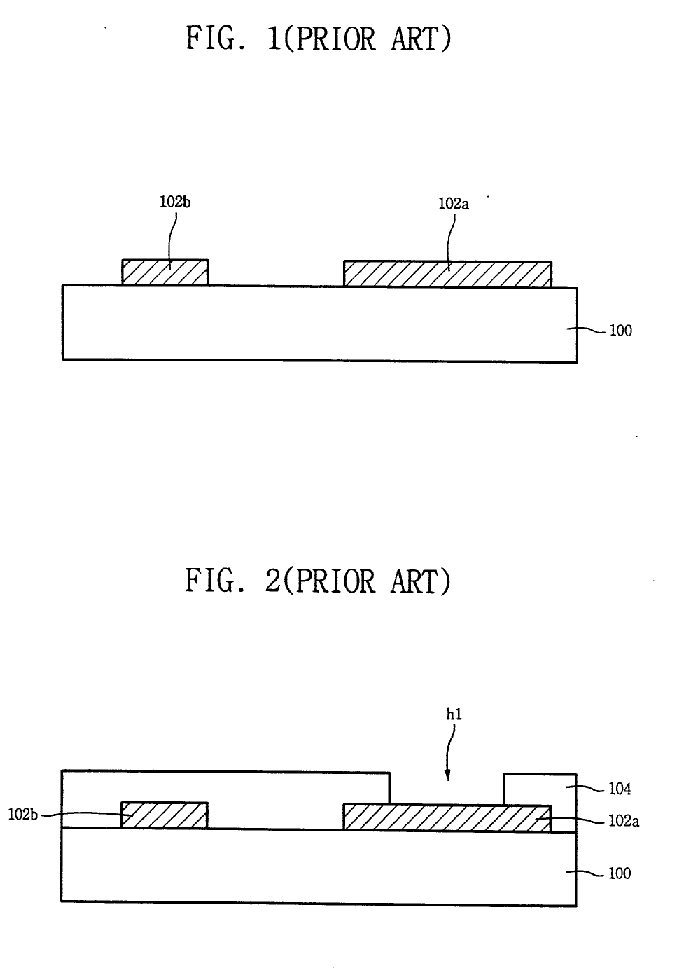

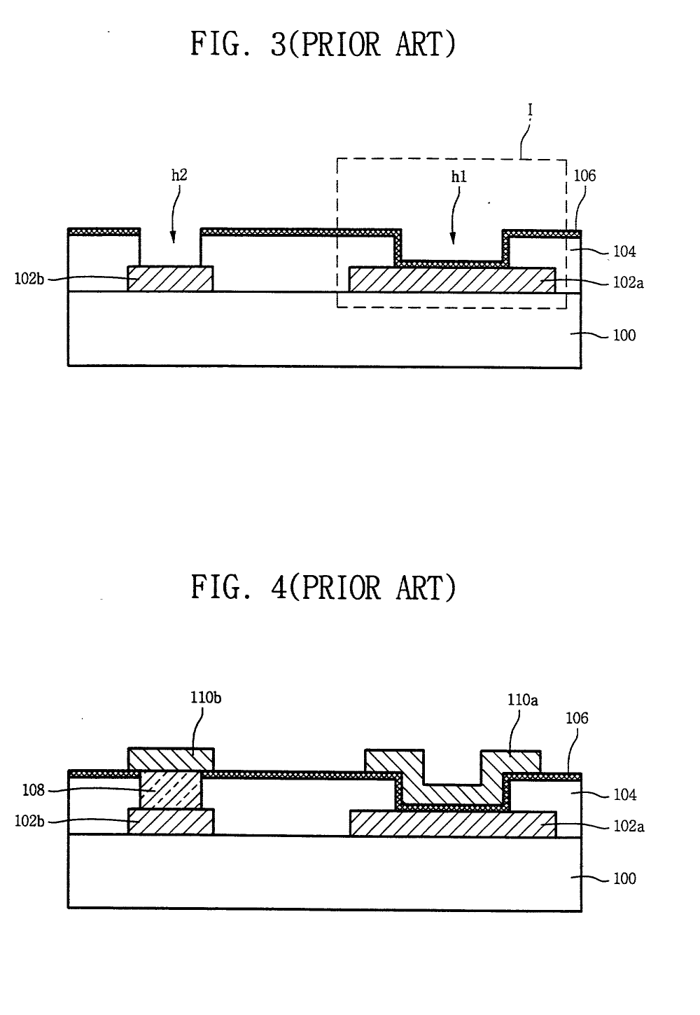

### DETAILED DESCRIPTION OF THE PREFERRED EMBODIMENTS

Korean patent application No. 98-43463, filed on Oct. 17, 1998, is incorporated by reference herein in its entirety. Reference now will be made in detail to the preferred embodiments of the present invention, examples of which are illustrated in the accompanying drawings. In the drawings, like reference numerals denote like embodiments.

When a certain layer is described to be “on” or “above” another layer or substrate, the certain layer may directly exist on the other layer or substrate and one or more additional layers may be interposed between the certain layer and the other layer or substrate. An analogous definition is intended for the words “below” and “under.”

A preferred feature of the present invention is a semiconductor integrated circuit capacitor having a MIM structure whose fabricating process is altered to simultaneously form the first via hole h1 in a capacitor formation part and the second via hole h2 in a wire line formation part when forming and etching the dielectric layer. In this embodiment, a spacer and a conductive plug preferably are formed respectively on inner sidewalls of the first via hole and on the second via hole. The spacer and conductive plug preferably are formed by a conductive layer depositing process, followed by an etch-back process, so that the side profile of the spacer present in the first via hole slopes slightly. Those skilled in the art are capable of successively depositing (i.e. forming) and etching layers on an integrated circuit using methods known in the art. For example, layers can be deposited (or formed) using various deposition techniques, like random metallization, chemical vapor deposition (CVD), plasma deposition, and the like. Selective etching also can be effected using, for example, photoresist compositions and masks.

In accordance with the invention, the method of making the semiconductor integrated circuit capacitor preferably is different from the conventional process by forming the first and second via holes simultaneously. The method also preferably is different from the conventional process by forming a dielectric layer such that the side profile of the first via hole slopes slightly by using a sloping spacer made of the conductive layer material. The inventive method therefore employs either feature alone, or both features in combination. The sloping spacer preferably has a diameter near the lower electrode that is smaller than the diameter further away from the lower electrode. In addition, this sloping spacer forming sloping sides of the first via hole prevents disconnection of the dielectric layer on both lower edges of the first via hole thereby enhancing the yield. The inventive capacitor, method of making it, as well as particularly preferred embodiments thereof, now will be described as follows with reference to FIGS. 6 to 10.

FIGS. 6 to 10 illustrate a capacitor and a method of making the capacitor having a MIM structure. The capacitor of the invention preferably is used in a logic and/or analog circuit. A preferred method of making the capacitor is described below.

FIG. 6 illustrates the formation (i.e., deposition) of a first conductive layer, preferably comprised of an aluminum (Al) and/or copper (Cu) alloy containing material or mixtures of these materials. The first conductive layer is formed on an insulating substrate 200 and can be deposited by any known techniques, but preferably is formed by a random metallization process. The first conductive layer then can be etched by using a photoresist pattern (not shown) as a mask to define a wire line formation part and a capacitor formation part, thereby each respectively forming a first wire line 202b and a lower electrode 202a on the substrate 200. Although not shown, it will be appreciated that the first wire line 202b can be connected electrically to a random wire line present in the insulating substrate 200 by means of, for example, a conductive plug, and the like.

In the inventive process, the layer patterning characteristic can be enhanced, and the contact resistance between the insulating layer 200 and the lower electrode 202a can be decreased by forming the first wire line 202b and the lower electrode 202a in a particularly preferred manner. In this embodiment, the first wire line 202b and the lower electrode 202a are formed and etched by using a photoresist pattern (not shown) as a mask to define both a capacitor formation part and a wire line formation part. The first wire line 202b and the lower electrode 202a preferably are formed by successively depositing a metal barrier layer (not shown), the first conductive layer and an anti-reflection layer (not shown) on the insulating substrate 200. The metal barrier layer and/or the anti-reflection layer can be: (i) a single-level structure containing a material selected from Ti, Ta, Mo, TiN, TiW, TaN, and MoN; and/or (ii) a multi-level structure containing materials selected from W—N, W—Si—N, Ta—Si—N, W—B—N, and Ti—Si—N; and/or (iii) mixtures of (i) and (ii).

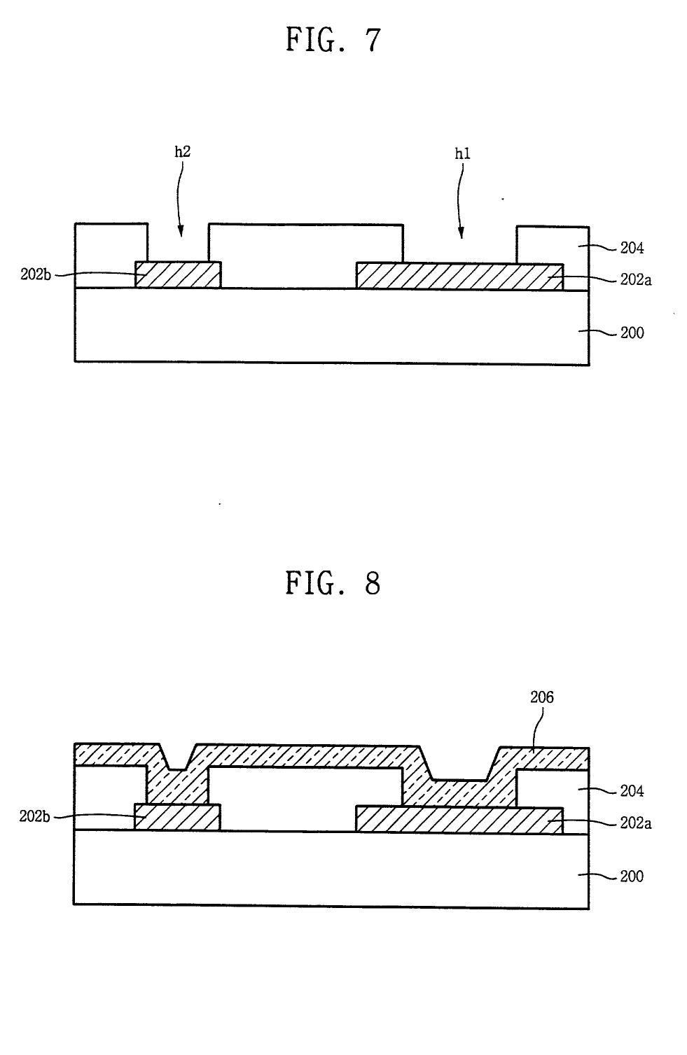

FIG. 7 shows the formation of a planarized interlevel insulating layer 204 on the insulating layer 200, which now includes the first wire line 202b and the lower electrode 202a. The planarized interlevel insulating layer 204 then can be etched, e.g., dry-etched, to expose a predetermined surface of the lower electrode 202a and a predetermined surface of the first wire line 202b. This etching process simultaneously produces a first via hole h1 and a second via hole h2. Preferably, the diameter of via hole h1 is larger than the diameter of via hole h2, as shown in FIG. 7. As shown in FIG. 7, via hole h1 has sidewalls 205 defined by the interlevel insulating layer 204 remaining after the etching process. Using the guidelines provided herein, skilled artisans are capable of using a photoresist pattern as a mask and/or etching the interlevel insulating layer 204 to expose the predetermined surfaces of the lower electrode 202a and first wire line 202b, and to simultaneously form via holes h1 and h2.

In the event that an oxide layer remains, or is formed on the first wire line 202b and lower electrode 202a, (the oxide layer can be an etching by-product generated in the process of etching the interlevel insulating layer 204, or it can be a natural oxide layer), RF sputter etching preferably is performed to remove any existing oxide layer. Skilled artisans are capable of carrying out a suitable RF sputter etching technique to remove any undesirable oxide layers.

Etching the interlevel insulating layer 204 can be performed by using any etching technique known in the art. Preferably, the interlevel insulating layer 204 is etched by wet-etching or by dry-etching. Alternatively, wet-etching and dry-etching can be performed together to etch the interlevel insulating layer 204 (e.g., performing wet-etching followed by dry-etching or performing dry-etching followed by wet-etching and then the dry-etching, etc.). Any combination of etching processes can be performed, and skilled artisans are capable of etching interlevel insulating layer 204 using the guidelines and techniques provided herein.

FIG. 8 illustrates forming a second conductive layer 206, preferably made of a tungsten (W) containing material, on the interlevel insulating layer 204. The second conductive layer 206 also is formed on and in the first and second via holes h1 and h2. Second conductive layer 206 can be deposited (of formed) on the layers noted above using techniques known in the art.

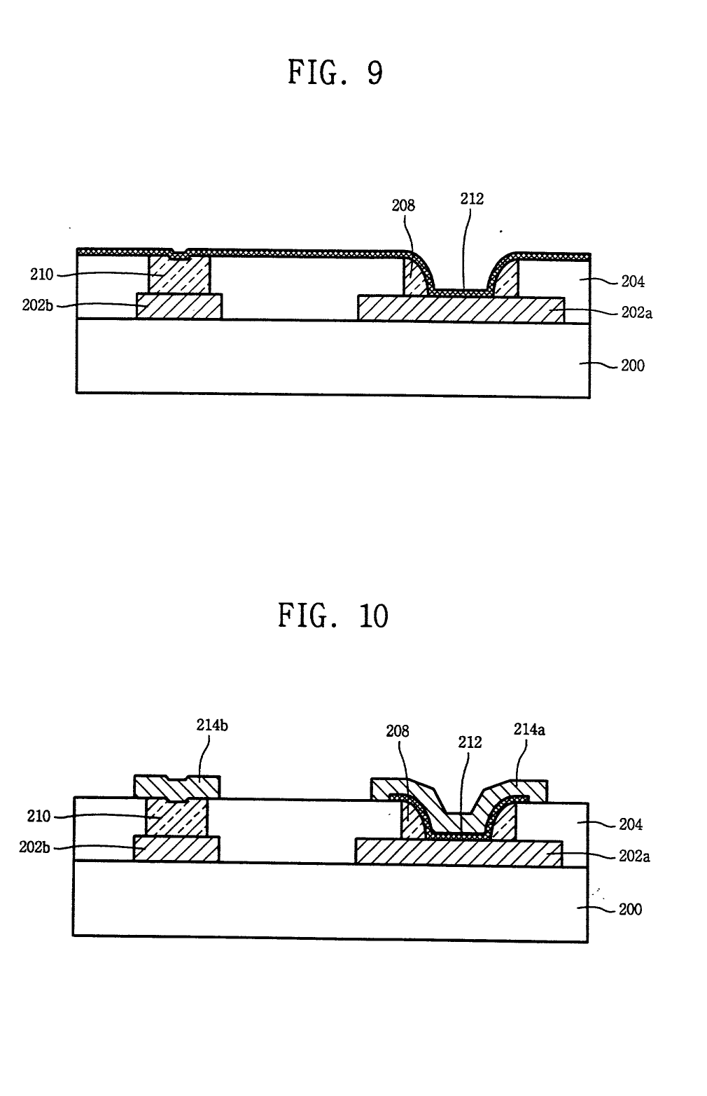

FIG. 9 illustrates etching back of the second conductive layer 206, preferably by anisotropic dry-etching, to form a spacer 208 (preferably made of a conductive layer comprising a tungsten containing material) on inner sidewalls 205 of the first via hole h1. Preferably, spacer 208 is a sloping spacer such that the diameter of the spacer 208 near the exposed surface of lower electrode 202a is smaller than the diameter of the spacer 208 further away from the exposed surface of lower electrode 202a. Etching back of the second conductive layer 206 also forms a conductive plug 210 (preferably made of a conductive layer comprising a tungsten containing material) in the second via hole h2. After selectively etching the second conductive layer 206, there is an exposed surface containing the spacer 208, conductive plug 210, the predetermined surface of the lower electrode 202a, and the remaining predetermined surfaces of the interlevel insulating layer 204.

Then, a dielectric layer 212 can be formed on the exposed surface using any layer deposition technique known in the art. Preferably, dielectric layer 212 is formed using a chemical vapor deposition (CVD) method. The dielectric layer 212 can be formed to have: (i) a single-level structure comprising an oxide layer (using deposition techniques employing, for example, Plasma Enhanced Oxide (PEOX), P—SiH₄, High Density Plasma (HDP)) or a nitride layer (layer (using deposition techniques employing, for example, Plasma Enhanced Silicon Nitride (PESiN)); and/or (ii) a multi-level structure comprised of the above single level structures (for example, oxide/nitride, nitride/oxide, oxide/nitride/oxide or nitride/oxide/nitride).

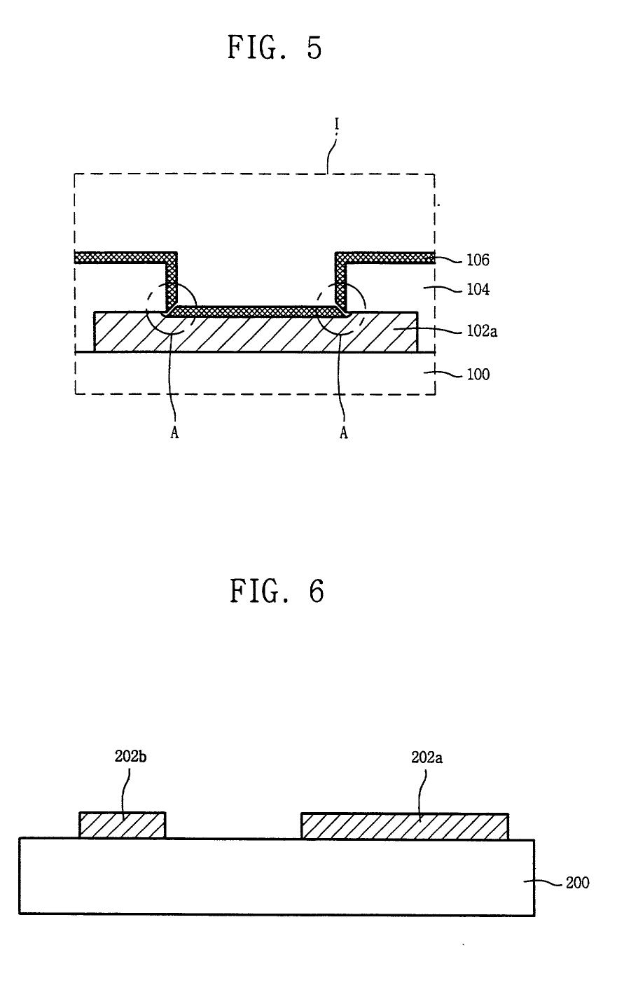

As described above, it is preferred that the dielectric layer 212 is formed in the first via hole h1 so that its side profile slopes slightly by virtue of the spacer 208. This configuration serves to prevent the inferior disconnection on both lower edges of the first via hole h1 that can occur in conventional capacitors, as illustrated in FIG. 5. In the conventional capacitors, disconnection on both lower edges of the via hole h1 occurs when depositing the dielectric layer, (which undercuts the lower electrode), if the side profile of the via hole h1 is not sloping, or which has an almost vertical gradient.

FIG. 10 illustrates the capacitor after removing the dielectric layer 212 at all of the areas except for the capacitor formation part, which includes the lower electrode 202a, the spacer 208 and the dielectric layer 212. The dielectric layer 212 can be removed by any technique capable of removing a dielectric layer and, preferably, is removed by using a photoresist pattern (not shown) as a mask to define a capacitor formation part.

After the portions of the dielectric layer 212 are removed, a third conductive layer, preferably made of an Al and/or Cu alloy containing material, can be formed on the interlevel insulating layer 204, the conductive plug 210, and the dielectric layer 212. The third conductive layer can then be etched by using a photoresist pattern (not shown) as a mask to define the capacitor formation part and a wire line formation part. A second wire line 214b and an upper electrode 214a can then be formed upon etching the third conductive layer, thereby completing the process of the invention. As shown in FIG. 10, the upper electrode 214a preferably is formed to have a width wider than the dielectric layer 212 in the first via hole h1. In addition, the second wire line 214b is connected to the conductive plug 210 in the second via hole h2.

In the invention, the layer patterning characteristic can be enhanced and the contact resistance decreased when the second wire line 214b and upper electrode 214a preferably are formed by successively depositing a metal barrier layer (not shown), the third conductive layer and an anti-reflection layer (not shown) on the interlevel insulating layer 204, the conductive plug 210, and the dielectric layer 212. The metal barrier layer and the anti-reflection layer can be made from the same materials described above. After depositing these layers, they then can be successively etched by using a photoresist pattern (not shown) as a mask, whereby the pattern defines a capacitor formation part and a wire line formation part. Artisans skilled in the art are capable of forming and etching these layers to form the respective parts of the semiconductor integrated circuit capacitor.

FIG. 10 also shows that the lower electrode 202a made from a conductive layer material can be formed on a predetermined part of the insulating layer 200. The interlevel insulating layer 204 then can be formed on the insulating layer 200 and the lower electrode 202a. The via hole h1 then preferably is formed to pass through the insulating layer 204 to thereby expose a predetermined part of the lower electrode 202a. After forming via hole h1, the spacer 208, preferably having a sloping surface as shown in FIG. 10 and preferably made from a conductive layer material, may be formed on sidewalls of the via hole h1. A dielectric layer 212 then can be formed on the bottom surface of the via hole h1 and at a predetermined part of the interlevel insulating layer 204 so that it includes the spacer 208. Finally, an upper electrode 214a, preferably made from a conductive layer material can be formed on a predetermined part of the interlevel insulating layer 204 and on the dielectric layer 212 thereby completing the capacitor having the above-mentioned MIM structure.

In accordance with a preferred embodiment of the invention, the capacitor is formed in such a manner that the side profile of the first via hole h1, by virtue of using the spacer 208, preferably made from a tungsten containing material, slopes slightly. In this embodiment, when the dielectric layer is deposited on the sloping spacer 208, disconnection in the dielectric layer on both lower edges of the via hole h1 does not occur, thus ensuring a uniformed capacitance and enhancing the yield.

It will be apparent to those skilled in the art that various modifications and variations can be made in the semiconductor integrated circuit capacitor and its fabrication method without departing from the spirit or scope of the invention. Thus, it is intended that the present invention cover the modifications and variations of this invention provided they come within the scope of the appended claims and their equivalents.

We claim:

1. A semiconductor integrated circuit capacitor, comprising:
an insulating substrate;
a lower electrode disposed on a predetermined part of the insulating substrate;
an interlevel insulating layer disposed on the insulating substrate and on the lower electrode;
a via hole having sidewalls, whereby the via hole passes through the interlevel insulating layer and exposes a predetermined surface of the lower electrode;
a spacer diposed on the sidewalls of the via hole;
a dielectric layer disposed on: (i) a bottom surface of the via hole adjacent to the predetermined surface of the lower electrode; (ii) a predetermined part of the insulating layer; and (iii) the spacer; and
an upper electrode disposed on a predetermined part of the interlevel insulating layer and disposed on the dielectric layer.

2. The capacitor as claimed in claim 1, wherein the spacer is made from a conductive layer comprising a tungsten containing material.

3. The capacitor as claimed in claim 1, wherein the dielectric layer has a structure selected from: (i) a single-level structure containing an oxide layer or nitride layer; or (ii) a multi-level structure containing layers selected from the group consisting of oxide layers, nitride layers, and mixtures thereof.

4. The capacitor as claimed in claim 3, wherein the oxide layer is made using a deposition technique employing Plasma Enhanced Oxide (PEOX), P—SiH₄, or High Density Plasma (HDP).

5. The capacitor as claimed in claim 3, wherein the nitride layer is made using a deposition technique employing Plasma Enhanced Nitride (PESiN).

6. The capacitor as claimed in claim 3, wherein the multi-level structure is selected from the group consisting of an oxide/nitride layer, a nitride/oxide layer, an oxide/nitride/oxide layer and a nitride/oxide/nitride layer.

7. The capacitor as claimed in claim 1, wherein the lower and upper electrodes are made of a material selected from an aluminum alloy, a copper alloy, and mixtures thereof.

8. The capacitor as claimed in claim 7, further comprising an anti-reflection layer disposed on the lower and/or upper electrodes' surface.

9. The capacitor as claimed in claim 8, wherein the anti-reflection layer has a structure selected from the group consisting of: (i) a single-level structure comprised of one or more materials selected from the group consisting of Ti, Ta, W, Mo, TiN, TiW, TaN, and MoN; (ii) a multi-level structure comprised of one or more materials selected from the group consisting of W—Si—N, Ta—Si—N, W—B—N, and Ti—SiN; and (iii) mixtures thereof.

10. The capacitor as claimed in claim 7, further comprising a metal barrier layer disposed on the lower and/or upper electrodes's surface.

11. The capacitor as claimed in claim 10, wherein the metal barrier layer has a structure selected from the group consisting of: (i) a single-level structure comprised of one or more materials selected from the group consisting of Ti, Ta, W, Mo, TiN, TiW, TaN, and MoN; (ii) a multi-level structure comprised of one or more materials selected from the group consisting of W—Si—N, Ta—Si—N, W—B—N, and Ti—SiN; and (iii) mixtures thereof.

12. A method of making a semiconductor integrated circuit capacitor, comprising:
providing an insulating substrate;
simultaneously forming a first wire line and a lower electrode on predetermined surfaces of the insulating substrate;
forming an interlevel insulating layer on the substrate, on the first wire line, and on the lower electrode;
selectively etching the interlevel insulating layer to expose a predetermined surface of the lower electrode and a predetermined surface of the first wire line thereby simultaneously forming in the interlevel insulating layer: (i) a first via hole having sidewalls and disposed above the lower electrode; and (ii) a second via hole disposed above the first wire line;
forming a conductive layer on the interlevel insulating layer and in the first and second via holes;
etching back the conductive layer to form: (i) a spacer on the sidewalls of the first via hole; (ii) a conductive plug in the second via hole; and (iii) an exposed surface containing the spacer, conductive plug, the predetermined surface of the lower electrode, and predetermined surfaces of the interlevel insulating layer;
forming a dielectric layer on the exposed surface;
removing the dielectric layer on the exposed surface except for a predetermined portion of the dielectric layer disposed on the spacer and predetermined surface of the lower electrode; and
simultaneously forming: (i) a second wire line connected to the conductive plug; and (ii) an upper electrode connected to the dielectric layer.

13. The method as claimed in claim 12, wherein the spacer is made from a conductive layer comprising a tungsten containing material.

14. The method as claimed in claim 12, wherein the dielectric layer has a structure selected from: (i) a single-level structure containing an oxide layer or nitride layer; or (ii) a multi-level structure containing layers selected from the group consisting of oxide layers, nitride layers, and mixtures thereof.

15. The method as claimed in claim 14, wherein the oxide layer is made using a deposition technique employing Plasma Enhanced Oxide (PEOX), P—SiH₄, or High Density Plasma (HDP).

16. The method as claimed in claim 14, wherein the nitride layer is made using a deposition technique employing Plasma Enhanced Nitride (PESiN).

17. The method as claimed in claim 14, wherein the multi-level structure is selected from the group consisting of an oxide/nitride layer, a nitride/oxide layer, an oxide/nitride/oxide layer and a nitride/oxide/nitride layer.

18. The method as claimed in claim 12, wherein the lower and upper electrodes are made of a material selected from an aluminum alloy, a copper alloy, and mixtures thereof.

19. The method as claimed in claim 18, further comprising an anti-reflection layer disposed on the lower and/or upper electrodes' surface.

20. The method as claimed in claim 19, wherein the anti-reflection layer has a structure selected from the group consisting of: (i) a single-level structure comprised of one or more materials selected from the group consisting of Ti, Ta, W, Mo, TiN, TiW, TaN, and MoN; (ii) a multi-level structure comprised of one or more materials selected from the group consisting of W—Si—N, Ta—Si—N, W—B—N, and Ti—Si—N; and (iii) mixtures thereof.

21. The method as claimed in claim 18, further comprising a metal barrier layer disposed on the lower and/or upper electrodes's surface.

22. The method as claimed in claim 21, wherein the metal barrier layer has a structure selected from the group consisting of: (i) a single-level structure comprised of one or more materials selected from the group consisting of Ti, Ta, W, Mo, TiN, TiW, TaN, and MoN; (ii) a multi-level structure comprised of one or more materials selected from the group consisting of W—Si—N, Ta—Si—N, W—B—N, and Ti—Si—N; and (iii) mixtures thereof.

23. The method as claimed in claim 12, further comprising, after forming the first and second via holes, RF sputter etching the interlevel insulating layer and the first and second via holes.

24. The method as claimed in claim 12, wherein the interlevel insulating layer is selectively etched by a process selected from the group consisting of dry-etching, wet-etching and dry/wet-combined etching.

25. The capacitor as claimed in claim 1, wherein the spacer disposed on the sidewalls of the via hole has a sloping surface.

26. The method as claimed in claim 12, wherein the spacer formed on the sidewalls of the via hole has a sloping surface.
